(19) United States
(12) Patent Application Publication
(10) Pub. No.: US 2025/0112125 A1
(43) Pub. Date: Apr. 3, 2025

(54) BRIDGES OVER METAL VOIDS IN INTEGRATED CIRCUIT PACKAGES

(71) Applicant: Intel Corporation, Santa Clara, CA (US)

(72) Inventors: Ranjul Balakrishnan, Bangalore (IN); Prabhat Ranjan, Bengaluru (IN); Prashant Dhirubhai Parmar, Gilbert, AZ (US); Naren Sreenivas Viswanathan, Gilbert, AZ (US); Russell Kevin Mortensen, Chandler, AZ (US)

(21) Appl. No.: 18/478,222

(22) Filed: Sep. 29, 2023

(51) Int. Cl. H01L 23/482; H01L 23/00; H01L 23/498; H01L 25/065

(52) U.S. Cl. CPC H01L 23/4821; H01L 23/49816; H01L 23/49822; H01L 24/16; H01L 24/48; H01L 25/0652; H01L 2224/16165; H01L 2224/16227; H01L 2224/48091; H01L 2224/48227; H01L 2924/1431; H01L 2924/1435; H01L 2924/15311; H01L 2924/19041

(57) ABSTRACT

Bridges over metal voids in integrated circuit packages are disclosed. An example a substrate for an electronic circuit comprising a first conductive layer having an aperture extending through the first conductive layer, the aperture aligned with a contact pad, the first conductive layer including an arm extending from a first location on a perimeter of the aperture to a second location on the perimeter of the aperture, and a second conductive layer adjacent to the first conductive layer, the second conductive layer including a metal trace positioned adjacent to the arm, the arm between the metal trace and the contact pad.

### FIELD OF THE DISCLOSURE

This disclosure relates generally to integrated circuits and, more particularly, to bridges over metal voids in integrated circuit packages.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are needed to facilitate stable transmission of high frequency data signals between different circuitry and/or increased power delivery.

### BRIEF DESCRIPTION OF THE DRAWINGS

FIG. 1 illustrates an example integrated circuit (IC) package constructed in accordance with teachings disclosed herein.

FIG. 2 illustrates a cross-sectional view of an example portion of the example package substrate of FIG. 1.

FIG. 3 illustrates an example conductive layer constructed in accordance with teachings disclosed herein.

FIG. 4 illustrates a detailed view of an example portion of the example conductive layer of FIG. 3.

FIG. 5 illustrates an example assembly constructed in accordance with teachings disclosed herein.

FIG. 6A illustrates a detailed view of an example sub-assembly of the assembly of FIG. 5.

FIG. 6B is a cross-sectional view of the example sub-assembly of FIG. 6A.

FIG. 7 illustrates another example conductive layer constructed in accordance with teachings disclosed herein.

FIG. 8 is a flowchart representative of an example method of manufacturing the example assembly 500, the example sub-assembly 530, the example assembly 700, and any other implementations described herein.

FIG. 9 is a top view of a wafer including dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

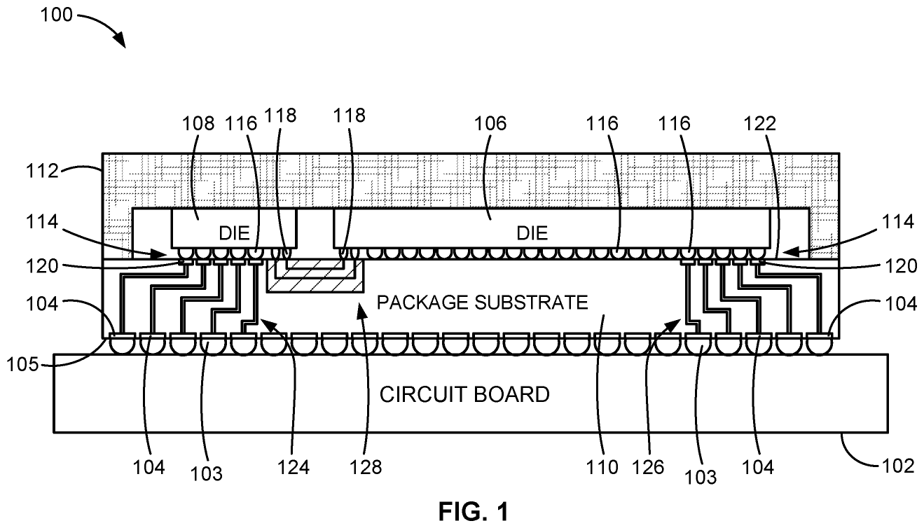

FIG. 1 illustrates an example IC package (e.g., a semiconductor package) 100 constructed in accordance with teachings disclosed herein. In the illustrated example, the IC package 100 is electrically coupled to an example circuit board 102 via an array of example balls 103 (e.g., a ball grid array (BGA)) coupled to associated contact pads 104 on an example mounting surface (e.g., a bottom surface) 105 of the package. In some examples, the IC package 100 may include other balls, pins, lands, and/or pads, in addition to or instead of the balls 103 and/or the contact pads 104, to enable the electrical coupling of the package 100 to the circuit board 102. In this example, the package 100 includes two example semiconductor (e.g., silicon) dies 106, 108 (sometimes also referred to as chips or chiplets) that are mounted to an example package substrate 110 and enclosed by an example package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is electrically and mechanically coupled to the substrate 110 via corresponding arrays of example interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the balls 103 and the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, example core bumps 116 and example bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and electrically coupled to example contact pads 120 on an example inner surface 122 of the substrate 110. The contact pads 120 on the inner surface 122 of the package substrate 110 are electrically coupled to the contacts pads 104 on the bottom (external) surface 105 of the substrate 110 (e.g., a surface opposite the inner surface 122) via example internal interconnects 124, 126 within the substrate 110. As a result, there is a complete signal path between the bumps 116 of the dies 106, 108 and the contact pads 104 (with associated balls 103) mounted to the circuit board 102 that pass through the contact pads 120 and the interconnects 124, 126 provided therebetween.

As used herein, bridge bumps are bumps on the dies through which electrical signals pass between different ones of the dies within an IC package. More particularly, bridge bumps differ from core bumps in that bridge bumps electrically connect two or more different dies via an interconnect bridge (e.g., example interconnect bridge 128 of FIG. 1) embedded in an underlying substrate (e.g., the package substrate 110). As represented in FIG. 1, core bumps 116 are typically larger than bridge bumps 118. In some examples, the interconnect bridge 128 and the associated bridge bumps 118 are omitted.

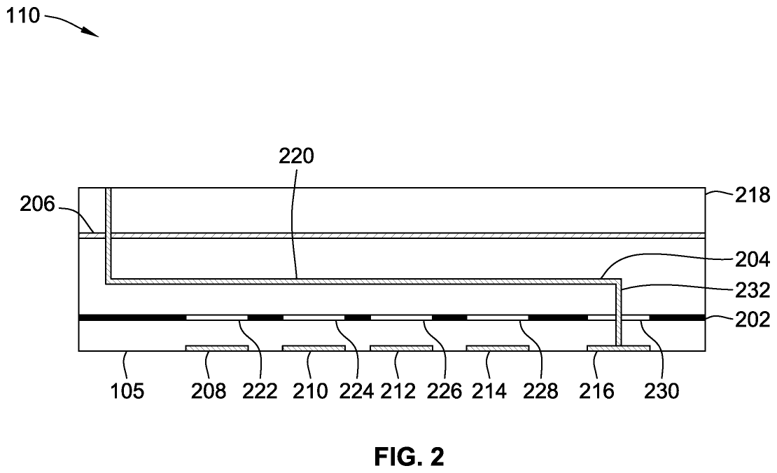

FIG. 2 illustrates a cross-sectional view of a lower portion of the example package substrate 110 of FIG. 1. Specifically, the lower portion of the package substrate 110 shown in FIG. 2 corresponds to layers of the package substrate 110 from a core of the package substrate 110 to the mounting surface 105 (e.g., the bottom surface) of the package substrate 110. The portion of the example package substrate 110 shown in FIG. 2 includes a first example conductive layer 202, a second example conductive layer 204, a third example conductive layer 206, and example pads 208, 210, 212, 214, 216. As shown in this example, the different conductive layers 202, 204, 206 and the pads 208, 210, 212, 214, 216 are separated (e.g., electrically isolated) by different layers of example dielectric material 218. While three example conductive layers 202, 204, 206 are shown, the package substrate 110 can have any suitable number of conductive layers. In this example, both the first and third conductive layers 202, 206 are conductive planes (e.g., defined by a relatively continuous sheet of metal) that can serve as reference planes (e.g., ground planes) in the package substrate 110. By contrast, the second conductive layer 204 includes a plurality of traces (e.g., defining signal paths) along the plane of the second conductive layer 204. In this example, one example trace 220 is shown that extends across the substrate in the cross-section shown in the illustrated example.

As shown in the illustrated example of FIG. 2, the first example conductive layer 202 (e.g., a reference plane layer, a ground plane layer, etc.) includes example metal voids 222, 224, 226, 228, 230 spaced apart from one another along a length of the first conductive layer 202. As used herein, the term “metal void” or “metal void region” (also referred to herein simply as “void”) refers to a region in a given conductive layer in which the metal associated with that layer is absent (e.g., has been removed). For example, a void can refer to a space, a cavity, a gap, and opening, etc. in the metal within an example conductive layer (e.g., the first conductive layer 202 in FIG. 2). However, in some examples, internal metal interconnects electrically coupled to other metal layers may nevertheless extend through any of the example voids 222, 224, 226, 228, 230. For example, the metal trace 220 is coupled to an example via 232 that extends through the void 230 to couple to the underlying pad 216.

In some examples, the pads 208, 210, 212, 214, 216 can couple to external interconnects. For example, at least one of the pads 208, 210, 212, 214, 216 can be implemented as the contact pads 104 in FIG. 1 and, in turn, can enable the electrical coupling of the package substrate 110 to the circuit board 102 (e.g., via the balls 103). The example metal voids 222, 224, 226, 228, 230 of the illustrated example are sometimes referred to as shadow voids because they align with, overlap, or “shadow” (e.g., are a comparable size and positioned adjacent to) the underlying pads 208, 210, 212, 214, 216. Such shadow voids 222, 224, 226, 228, 230 are included in the first conductive layer 202 in proximity to the corresponding pads 208, 210, 212, 214, 216 to reduce the relatively high pad capacitance arising from the relatively large size of the pads 208, 210, 212, 214, 216 (e.g., relative to the size of the traces and vias (e.g., the trace 220 and the via 232) in the package substrate 110). More specifically, the voids 222, 224, 226, 228, 230 serve to increase the pad impedance, thereby reducing the impedance discontinuity at the pads 208, 210, 212, 214, 216. In some examples, shadow voids can be implemented in multiple conductive layers (e.g., multiple reference plane layers) to increase the pad impedance to desired levels.

In some examples, as noted above, the first conductive layer 202 is an example reference plane layer 202 that provides a reference path (e.g., a ground path, return path, etc.) for current provided (e.g., induced) by the metal trace 220. For example, the return path of the current provided by the metal trace 220 is routed (e.g., directed) to the reference plane layer 202 which, in turn, confines or restricts the current to the reference plane layer 202. In some examples, absent the reference plane layer 202, a signal provided by the metal trace 220 coupled to an associated pad 216 may be free (e.g., unconfined) to capacitively couple with signals associated with other ones of the pads 208, 210, 212, 214 due to the physical proximity of the different signal paths. Such capacitive coupling can be referred to as crosstalk, which has detrimental effects on the signal performance of the package substrate 110 and, in turn, the IC package 100.

As shown in FIG. 2, the example voids 222, 224, 226, 228, 230 are gaps (e.g., spaces, cavities, openings, etc.) in the reference plane layer 202 that are devoid of metal corresponding to that layer. Routing metal traces (e.g., the metal trace 220) over these voids 222, 224, 226, 228, 230 can produce localized regions of capacitive coupling (e.g., through the voids 222, 224, 226, 228, 230) between the traces and the underlying pads 208, 210, 212, 214, 216. In other words, the voids 222, 224, 226, 228, 230 effectively remove the grounding effect of the reference plane layer 204. As such, these localized regions (e.g., regions where the metal trace 220 is routed across (e.g., over) any one of the voids 222, 224, 226, 228, 230) are susceptible to crosstalk and can deteriorate the electrical performance of the IC package 100. Although FIG. 2 is described as corresponding to a portion of the package substrate 110 of FIG. 1, teachings disclosed herein apply to other types of electronic circuit substrates. For instance, the examples disclosed herein can be implemented in a printed circuit board (e.g., the printed circuit board (PCB) 102 of FIG. 1) in addition to or instead of in the package substrate 110. Thus, while examples disclosed herein are described with reference to package substrates, it should be understood that they are not so limited and may be similarly employed in printed circuit boards and/or other suitable electronic circuit substrates.

Previous solutions to reduce capacitive coupling at void regions include routing metal traces (e.g., the metal trace 220) around the void regions (e.g., to circumvent the void regions). For example, the example metal trace 220 can be positioned in a lateral direction away from the void regions. However, this may result in overcrowding metal traces at other locations on the conductive layer (e.g., between the voids, around the voids, etc.). Such overcrowding can worsen the effects of crosstalk and impedance discontinuity within an example IC package.

Examples disclosed herein provide bridge connections (e.g., bridges) disposed within the metal void regions in the corresponding conductive layer (e.g., the reference plane layer 202) and traverse the void regions (e.g., extend through or across the void regions along the plane of the conductive layer. Examples disclosed herein position metal traces (in an adjacent conductive layer such as the second conductive layer 204) adjacent to (e.g., aligned with) the bridges within a corresponding metal void to provide metal within the reference plane that separates (e.g., is positioned between) an underlying pad on one side of the reference plane and a metal trace on the other side of the reference plane that passes directly over the metal void region. As such, disclosed examples reduce capacitive coupling between adjacent conductive layers by providing bridges across void regions in the conductive layers. Thus, disclosed examples improve the electrical performance of example IC packages by implementing bridges across (e.g., through) example void regions in an example conductive layer.

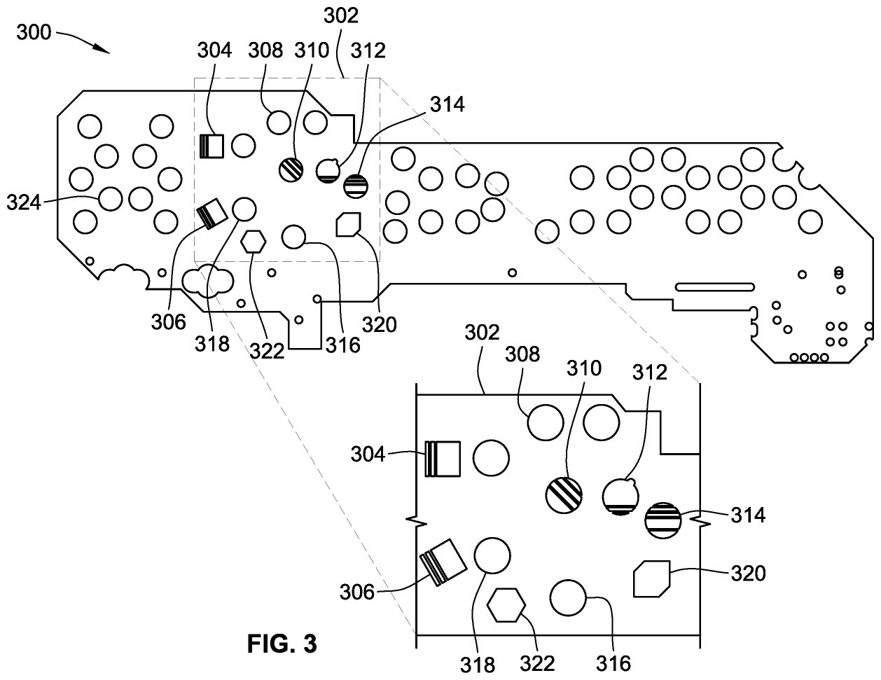

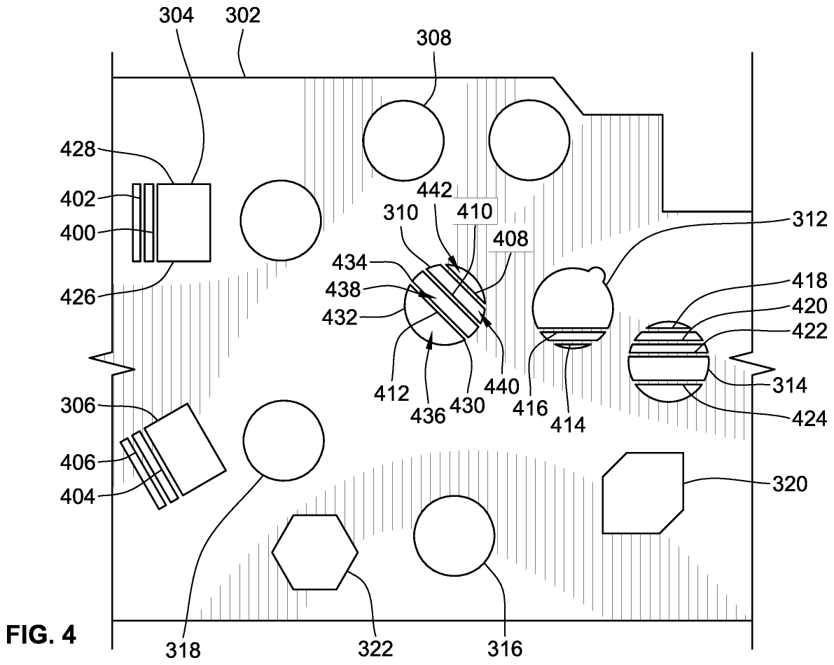

FIG. 3 illustrates an example conductive layer 300 constructed in accordance with teachings disclosed herein. FIG. 4 illustrates a detailed view of an example portion 302 of the conductive layer 300 of FIG. 3. In some examples, the conductive layer 300 corresponds to a conductive layer within a package substrate (e.g., corresponds to the first conductive layer 202 of the package substrate 110 shown in FIG. 2). In other examples, the conductive layer 300 corresponds to a conductive layer within a PCB (e.g., the PCB 102 of FIG. 1). The example conductive layer 300 includes example metal voids (e.g., apertures, cavities, etc.) 304, 306, 308, 310, 312, 314, 316, 318, 320, 322, 324 extending through the conductive layer 300. The example voids 304, 306, 308, 310, 312, 314, 316, 318, 320, 322, 324 are spaced apart from one another and distributed throughout the conductive layer 300. In this example, the voids 304, 306 have a rectangular (e.g., square) shape, the voids 308, 310, 312, 314, 316, 318 have a circular shape, and the voids 320, 322 have a hexagonal shape. In other words, an example perimeter surrounding or defining each of the voids 304, 306 is rectangular, an example perimeter surrounding or defining each of the voids 308, 310, 312, 314, 316, 318, 324 is circular, and an example perimeter surrounding or defining each of the voids 320, 322 is hexagonal. In some examples, the conductive layer 300 may include any number of example voids (e.g., 2, 15, 20, etc.). Further, the example voids 304, 306, 308, 310, 312, 314, 316, 318, 320, 322, 324 may have any suitable shape (e.g., trapezoidal, octagonal, etc.).

Turning to FIG. 4, the example portion 302 of the conductive layer 300 (FIG. 3) includes example bridges (e.g., bridge connections, arms, bridge segments, linear segments, segments, etc.) 400, 402, 404, 406, 412, 410, 408, 414, 416, 418, 420, 422, 424 that extend across each of the voids 304, 306, 310, 312, 314. For example, the bridges 400, 402 extend from a first example side 426 of the void 304 to a second example side 428 of the void 304. Thus, unlike known metal voids that are typically devoid of all metal associated with the associated conductive layer, example voids disclosed herein include at least some metal associated with the bridges extending therethrough. Alternatively, as discussed further below, any one of the voids 304, 306, 310, 312, 314 can be described or characterized as a group or set of sub-voids (e.g., individual openings devoid of metal associated with the conductive layer) that are separated or demarcated by the bridges 400, 402, 404, 406, 412, 410, 408, 414, 416, 418, 420, 422, 424. In this example, the example bridges 400, 402 are substantially perpendicular to the first side 426 and/or the second side 428. As used herein, substantially perpendicular means exactly perpendicular or within 5 degrees of exactly perpendicular. Further, the example bridge 412 extends from a first example location 430 on an example perimeter 432 of the void 310 (e.g., a first portion of the void 310 facing in a first direction) to a second example location 434 on the perimeter 432 of the void 310 (e.g., a second portion of the void 310 facing in a second direction different than the first direction). In some examples, the different portions of a void (at which the opposite ends of a bridge are located) face in substantially opposite directions (as is the case of the example bridge 412 in the void 310). In some examples, the different portions of a void (at which the opposite ends of a bridge are located) may not face in exactly opposite directions based on the shape of the void and the position of the bridge (as in the case of the example bridge 408 in the void 310).

As noted above, in some examples, any one of the example voids 304, 306, 310, 312, 314 may be referred to as (or represented as) a group or set of cavities (e.g., sub-voids) that are arranged to collectively correspond to or define a given one of the main voids 304, 306, 310, 312, 314. For example, the bridge 412 separates a first example cavity 436 in the conductive layer 300 from a second example cavity 438 in the conductive layer 300. Further, the bridge 410 separates the second example cavity 438 from a third example cavity 440 and the bridge 408 separates the third example cavity 440 from a fourth example cavity 442. As such, the example void 310 can be represented as the example cavities 436, 438, 440, 442 (e.g., group of cavities).

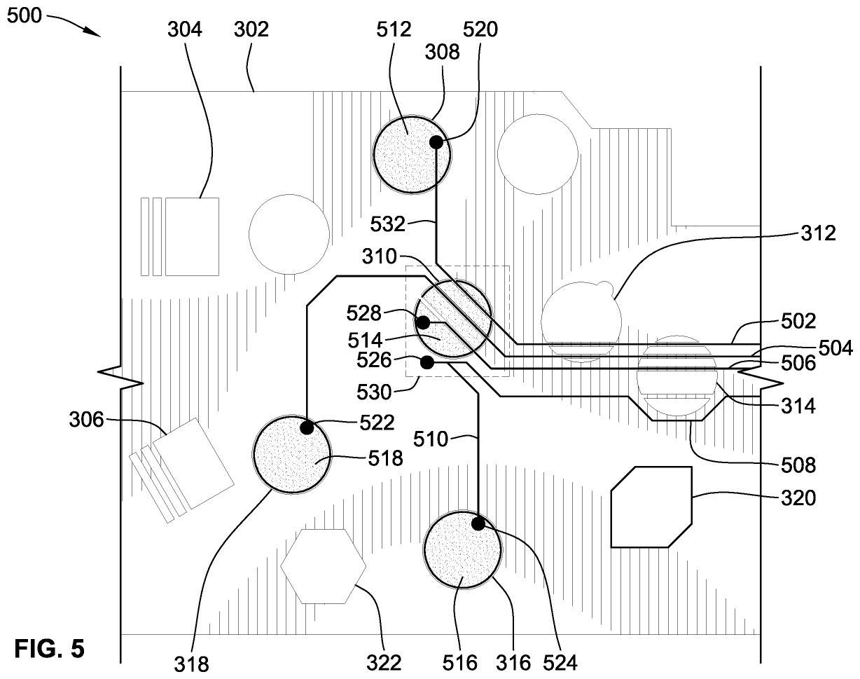

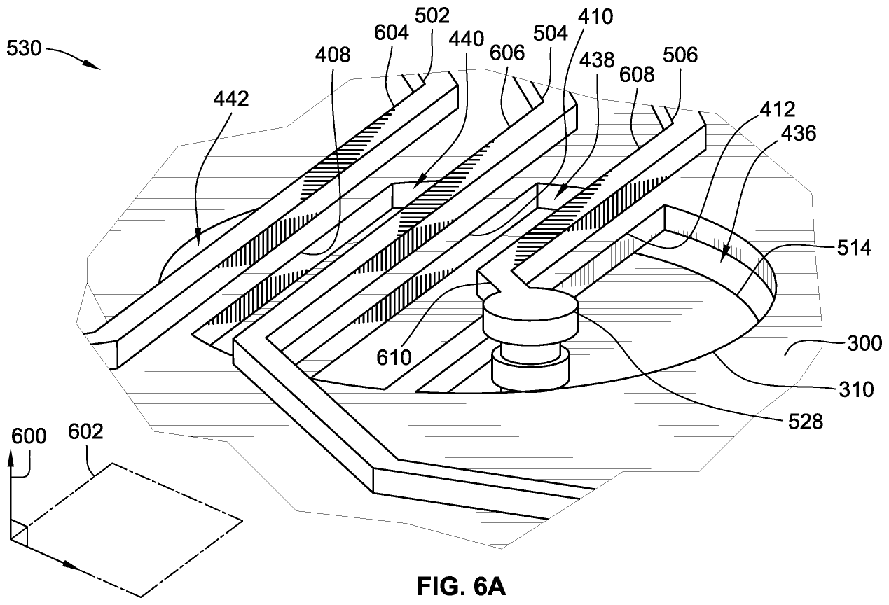

FIG. 5 illustrates an example assembly 500 constructed in accordance with teachings disclosed herein. The example assembly 500 includes the example portion 302 of the conductive layer 300, example metal traces 502, 504, 506, 508, 510, example contact pads 512, 514, 516, 518, example via pads 520, 522, 524, 526, 528, and example sub-assembly 530. FIG. 6A is a detailed perspective view of the example sub-assembly 530 of FIG. 5. FIG. 6B is a cross-sectional perspective view of the sub-assembly 530 of FIG. 6A.

As shown in the illustrated examples, the void 308 is aligned with the contact pad 512, the void 310 is aligned with the contact pad 514, the void 316 is aligned with the contact pad 516, and the void 318 is aligned with the contact pad 518. That is, the example voids 308, 310, 316, 318 are shadow voids for the associated contact pads 512, 514, 516, 518. The example metal traces 502, 504, 506, 508, 510 are positioned adjacent to the conductive layer 300 (e.g., in an adjacent conductive layer different than the conductive layer 300). For instance, in some examples, the conductive layer 300 of FIG. 5 may correspond to the first conductive layer 202 of FIG. 2 with the metal traces 502, 504, 506, 508, 510 of FIG. 5 corresponding to the second conductive layer 204. In this example, the contact pads 512, 514, 516, 518 are positioned on an opposite side of the conductive layer 300 to that of the metal traces 502, 504, 506, 508, 510. That is, from the viewpoint shown in FIG. 5, the metal traces 502, 504, 506, 508, 510 are the closest to the viewer and the contact pads 512, 514, 516, 518 are the farther away from the viewer with the conductive layer 300 disposed therebetween. In some examples, conductive balls (e.g., the balls 103) are coupled to the contact pads 512, 514, 516, 518. In such examples, the balls would be farther into the drawing of FIG. 5 (from the viewpoint shown) than the contact pads 512, 514, 516, 518. In some examples, the metal traces 502, 504, 506, 508, 510 are positioned between the conductive layer 300 and an example semiconductor die (e.g., the die 106 of FIG. 1, the die 108 of FIG. 1, etc.). Further, the example contact pads 512, 514, 516, 518 can be positioned on a first side of an example package substrate (e.g., at the mounting surface 105 of the package substrate 110 of FIG. 1) and the example semiconductor die (e.g., either one of the dies 106, 108 of FIG.) can be attached to a second side of the example package substrate 110 (e.g., the inner surface 122 of the package substrate 110 of FIG. 1). As such, the conductive layer 300, the contact pads 512, 514, 516, 518, and the metal traces 502, 504, 506, 508, 510 can be positioned between the example conductive balls (coupled to the exterior side of the contact pads 512, 514, 516, 518) and the example semiconductor die.

In some examples, the assembly 500 can include a second example conductive layer having example voids. For example, the second conductive layer can be positioned between the conductive layer 300 and the contact pads 512, 514, 516, 518. The second example conductive layer can include an example void aligned with a corresponding one of the voids 304, 306, 308, 310, 312, 314, 316, 318, 320, 322, 324. In other examples, the second conductive layer can be positioned between the conductive layer 300 and a third example conductive layer including the metal traces 502, 504, 506, 508, 510.

As shown in FIG. 5, the example metal traces 502, 504, 506, 508, 510 extend along the conductive layer 300 between different ones of the voids 308, 310, 312, 314, 316, 318. For example, an example portion (e.g., segment, terminal, lead, etc.) 532 of the metal trace 502 extends away from the void 310 towards the void 308. The example portion 532 is electrically coupled to the contact pad 512. In particular, the portion 532 is electrically coupled to the contact pad 512 by one or more vias extending through the void 308 (e.g., in a direction transverse to the plane of the conductive layer 300) from the contact pad 512 to the via pad 520 at the end of the portion 532 of the metal trace 502.

Turning to FIGS. 6A and 6B, the example sub-assembly 530 includes the example void 310, the example contact pad 514, the example metal traces 502, 504, 506, the example via pad 528, and the example conductive layer 300. The example sub-assembly 530 may be included in an example package substrate (e.g., the package substrate 110 of FIG. 1). For example, the conductive layer 300 may be one of a plurality of conductive layers in the package substrate 110. The example contact pad 514 may be positioned on a first side of the package substrate 110 (e.g., the mounting surface 105). Further, an example semiconductor die (e.g., the dies 106, 108) may be positioned on a second side of the package substrate (e.g., mounted via the interconnects 114). In such examples, at least one of the cavities 436, 438, 440, 442 (collectively corresponding to the void 310) can be between the contact pad 514 and at least one of the dies 106, 108 in a direction generally aligned to example axis 600. In this example, the axis 600 is generally normal (e.g., within 5 degrees) to an example plane 602 of the conductive layer 300. Additionally, at least one of the bridges 408, 410, 412 can be between the contact pad 514 and at least one of the dies 106, 108 in the direction generally aligned to the axis 600. Further, a second example conductive layer can be positioned between the conductive layer 300 and at least one of the dies 106, 108. The second example conductive layer can include the metal traces 502, 504, 506 (as well as the via pad 528 at the end of the metal trace 506). As such, the example metal traces 502, 504, 506 can be positioned between the bridges 408, 410, 412 and at least one of the dies 106, 108 in the direction generally aligned to axis 600.

As shown in FIGS. 6A and 6B, a first example portion 604 of the metal trace 502 is positioned adjacent to the bridge 408, a second example portion 606 of the metal trace 504 is positioned adjacent to the bridge 410, and a third example portion 608 of the metal trace 506 is positioned adjacent to the bridge 412. Further, the bridge 408 is between the portion 604 and the contact pad 512, the bridge 410 is between the portion 606 and the contact pad 512, and the bridge 412 is between the portion 608 and the contact pad 512. More particularly, as shown in the illustrated example, each of the portions 604, 606, 608 of the metal traces 502, 504, 506 is aligned with and extends substantially parallel to the corresponding bridge 408, 410, 412. As used herein, substantially parallel means exactly parallel or within 5 degrees of exactly parallel. Positioning the bridges within metal voids between metal traces and contact pads as shown in FIG. 5 has been found to significantly reduce cross-talk between the traces and the adjacent contact pads (and associated conductive balls). As a result, it is possible to reduce the total number and/or spacing of conductive layers in a package substrate and/or to increase routing density in the vicinity of metal voids while maintaining and/or improving signal integrity. Further, the increase in trace impedance (due to the trace crossing directly over a void) is compensated for by the bridges for better intersymbol interference (ISI) performance.

In some examples, the sub-assembly 530 may include a dielectric material (e.g., the dielectric material 218 shown in FIG. 2). For example, the dielectric material may at least partially fill (e.g., fill, completely fill, etc.) the void 310 as well as the space between the adjacent conductive layers. Additionally or alternatively, the dielectric material can be between at least one of the bridges 408, 410, 412 and the contact pad 512. In some examples, the dielectric material can separate the bridges 408, 410, 412 from the contact pad 512. In some examples, the contact pad 512 may be electrically and mechanically coupled to a conductive ball (e.g., the balls 103). For example, the contact pad 512 can be positioned between at least one of the bridges 408, 410, 412 and the conductive ball. Accordingly, the contact pad 512 (together with the conductive ball) can facilitate connection with a PCB (e.g., the circuit board 102 of FIG. 1).

As shown in FIGS. 6A and 6B, the example bridges 408, 410, 412 extend in a first direction across the void 310. Further, the example portions 604, 606, 608 extend along the first direction. Accordingly, the portions 604, 606, 608 are shaped to follow the bridges 408, 410, 412. In this example, all of the bridges 408, 410, 412 and the corresponding portions 604, 606, 608 are substantially parallel to one another. In other examples, one or more of the bridge-trace portion pairs can be angled relative to the other bridge-trace portion pairs. Further, in the illustrated example, the metal trace 506 includes another example portion 610 that extends along a second direction different from the first direction across (e.g., over) the void 310. In other words, the example portion 610 is angled relative to the portion 608, and the portions 608, 610 connect at a point within the region directly adjacent to and defined by the void 310. That is, the example portion 610 is positioned within an area defined by a projection in the direction of the axis 600 of the example perimeter 432 (FIG. 4) of the void 310. Further, the example portion 610 is electrically coupled to the via pad 528 which, in turn, is electrically coupled to the contact pad 514 by way of a via stack extending through the void 310 in a direction generally parallel to the axis 600. More particular, the via stack includes a first via 612 extending from the via pad 528 to a second via pad 614 (in the conductive layer 300 and, thus, within the void 310), and a second via 616 extending from the second via pad 614 to the contact pad 514.

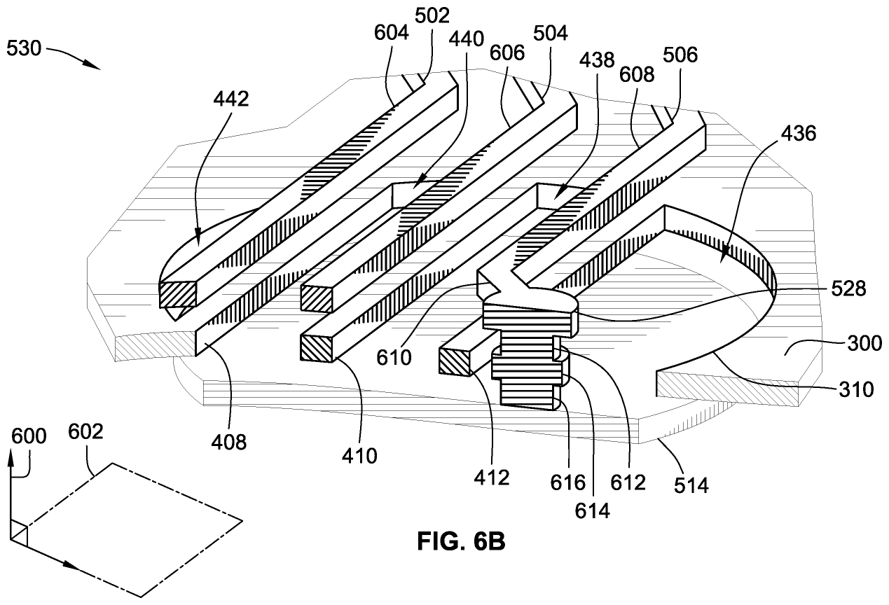

FIG. 7 illustrates another example assembly 700 constructed in accordance with teachings disclosed herein. The example assembly 700 of FIG. 7 is similar to the example assembly 500 of FIG. 5. For example, the assembly 700 includes an example conductive layer 702, example voids 704, 706, 708, 710, 712, 714, 716, example bridges 718, 720, 722, 724, 726, 728 example metal traces 730, 732, 734, 736, and example contact pads 738, 740.

As shown in FIG. 7, the example bridges 718, 720, 722 extend from a first example side 742 of the void 704 to a second example side 744 of the void 704. Additionally, the example bridges 724, 726 extend from a first example side 746 of the void 706 to a second example side 748 of the void 706. The example metal trace 730 extends along (e.g., is aligned with but is in a different conductive layer than) the bridge 726 and the bridge 718. In particular, the metal trace 730 extends away from the first side 746 of the void 706 towards the second side 744 of the void 704. An example portion 750 of the metal trace 730 is positioned between the first side 742 of the void 704 and the second side 744 of the void 704. Further, the example portion 750 is electrically coupled to the contact pad 740 through a via stack associated with an example via pad 752 at an end of the metal trace 730.

In some examples, the bridges 718, 720, 722, 724, 726, 728 (or any other bridges disclosed herein) have one or more bends. For example, the example bridge 728 includes a bend. In some examples, the bend corresponding to the bridge 728 is oriented in the same plane as the conductive layer 702. In other words, the bend in the bridge 728 is substantially level (e.g., within 5 degrees) with the conductive layer 702. The bridge 728 includes a first example segment 754 angled (e.g., bent, sloping, etc.) relative to a second example segment 756. In other words, the first segment 754 extends in a first direction across the void 708 and the second segment 756 extends in a second direction across the void 708, the second direction different from the first direction. The example bridge 728 spans the void 708 from a first example side 758 of the void 708 to a second example side 760 of the void 708. The first example segment 754 extends in a direction substantially perpendicular to the first side 758. However, the second example segment 756 extends away from the second side 760 at an angle (e.g., 45 degrees, 60 degrees, etc.) relative to the side 760. Further, the first segment 754 connects to the second segment 756 at a point between the sides 758, 760 of the void 708. In some examples, an example bridge can have multiple bends (e.g., bridge 718). In some examples, the metal traces 730, 732, 734, 736, can be shaped (e.g., routed, oriented, positioned, etc.) to follow a shape (e.g., a bend) of any of the bridges 718, 720, 722, 724, 726, 728. For example, an example metal trace can be shaped (e.g., positioned) to follow the first segment 754 and the second segment 756. In another example, the bridge 718 includes at least one bend (e.g., a first segment that is angled relative to a second segment). The metal trace 730 has a shape aligned with the shape of the bridge 718.

The first example segment 754 of the bridge 728 in the void 708 defines a first edge of an example cavity 762 and the second segment 756 defines a second edge of the cavity 762. Further, the first side 758 can define a third edge of the cavity 762 and the second side 760 can define a fourth edge of the cavity 762. In some examples, an example fillet may be provided in the conductive layer 702. For example, the example fillets 764, 766, 768, 770, 772, 774, 776, 778, 780, 782 can be provided in the conductive layer 702 to fill corners of cavities (e.g., the cavity 762). The example fillet 764 extends from a side of the second segment 756 to the second side 760 of the void 708. In other words, the example fillet 764 is positioned between the side of the second segment 756 and the second side 760. As such, the fillet 764 can at least partially fill the cavity 762. In some examples, the fillets are positioned at (e.g., reinforce) intersections of the bridges and the perimeter of a corresponding one of the voids. In the example of FIG. 7, outlines of the example fillets 764, 766, 768, 770, 772, 774, 776, 778, 780, 782 are denoted with a dashed lines. However, in some examples, the fillets 764, 766, 768, 770, 772, 774, 776, 778, 780, 782 are extensions or portions of the conductive layer 702. As used herein, the term “fillet” refers to a portion of a bridge, a portion of a conductive layer, etc. that fills in a space between (e.g., at the corner or intersection of) two edges of metal extending at angles relative to one another.

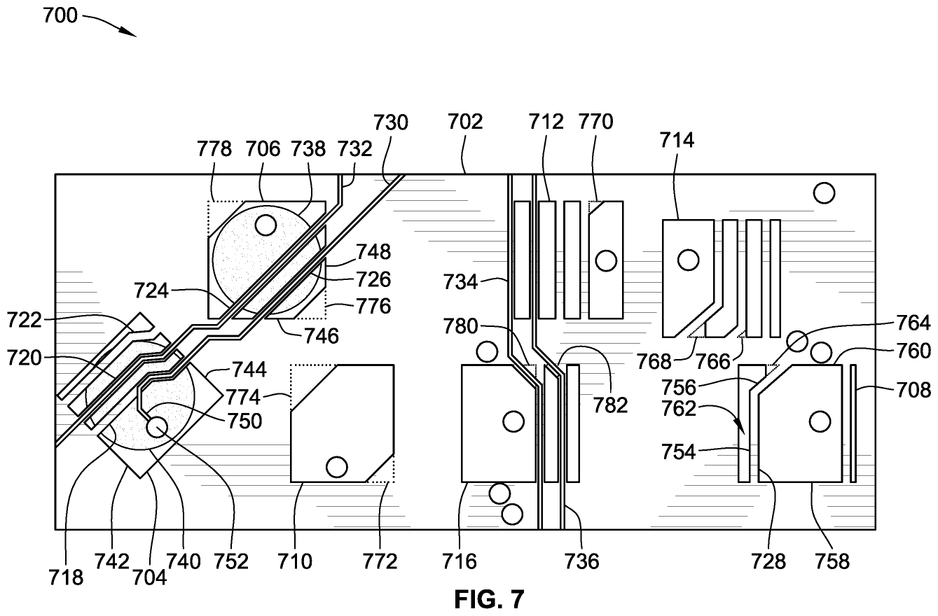

FIG. 8 is a flowchart representative of an example method 800 of manufacturing the example assembly 500, the example sub-assembly 530, the example assembly 700 and any other implementations described herein. In some examples, some or all of the operations outlined in the example method of FIG. 8 are performed automatically by fabrication equipment that is programmed to perform the operations. Although the example method of manufacture is described with reference to the flowchart illustrated in FIG. 8, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method 800 begins at block 802, at which a first example conductive layer including an example metal trace is provided. For example, an example conductive layer including the metal traces 502, 504, 506, 508, 510, is provided, an example conductive layer including the metal traces 730, 732, 734, 736, is provided, etc. In some examples, the metal traces are provided on previously manufactured layers of material in a package substrate and/or in a PCB. At block 804, a first example dielectric layer is deposited on the metal trace. In some examples, the first dielectric layer is added through a lamination process.

At block 806, a second example conductive layer including an example void and an example bridge to align with the metal trace is provided on the first dielectric layer. For example, the conductive layer 300 can be provided. The conductive layer 300 includes the example voids 304, 306, 308, 310, 312, 314, 316, 318, 320, 322, 324 and the example bridges 400, 402, 404, 406, 408, 410, 412, 414, 416, 418, 420, 422, 424. The bridge 408 is aligned with the metal trace 502, the bridge 410 is aligned with the metal trace 504, and the bridge 412 is aligned with the metal trace 506. Further, the conductive layer 702 includes the example voids 704, 706, 708, 710, 712, 714, 716 and the example bridges 718, 720, 722, 724, 726, 728. The bridge 720 is aligned with the metal trace 732 and the bridge 718 is aligned with the metal trace 730. The bridge 724 is aligned with the metal trace 732 and the bridge 726 is aligned with the metal trace 730.

At block 808, a second example dielectric layer is deposited on the second conductive layer. In some examples, the second dielectric layer will extend into and fill the example void. For example, the material of the second dielectric layer may fill at least one of the voids 308, 310, 316, 318, 704, 706. Further, the material of the second dielectric layer may surround and/or enclose the bridges 408, 410, 412, 718, 720, 722, 724, 726 (e.g., between the first and second dielectric layers).

At block 810, conductive metal extending through the void and the first and second dielectric layers to connect to the example metal trace is provided. In some examples, block 810 is implemented in different stages. For instance, in some examples, after block 804 and before block 808, a first via is provided that extends through the first dielectric layer with a via pad provided on the exposed surface of the first dielectric layer. Then, after block 808, a second via is added through the second dielectric layer so as to be electrically coupled to the via pad (and the associated first via), thereby defining a via stack extending though both the first and second dielectric layers. For example, the portion 610 of the metal trace 506 is coupled to the contact pad 512 through the void 310 by way of the first via 612, the second via pad 614, and the second via 616. Additionally, the example portion 750 of the metal trace 730 is coupled to the contact pad 740 through the void 704.

At block 812, a contact pad aligned with the void is added. For example, the contact pad 514 is to be electrically coupled to the conductive metal (e.g., the via pads 528, 614 and the vias 612, 616) extending through the dielectric layers to electrically connect the contact pad 514 to the trace 506. Further, the contact pad 740 is to be electrically coupled to the conductive metal (e.g., the via pad 752) extending through the dielectric layers to electrically connect the contact pad 740 to the portion 750 of the metal trace 730. In some examples, a conductive ball is also added to the contact pad. For example, one of the conductive balls 103 can be added to at least one of the contact pads 512, 514, 516, 518, 738, 740. Then, the process ends.

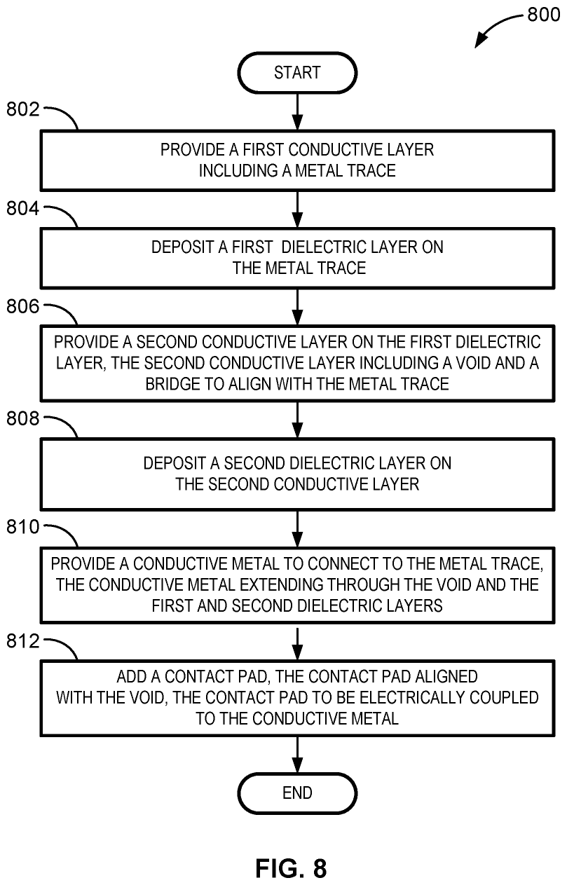

The example conductive layer 300 of FIGS. 3 and 4, the example assembly 500 of FIG. 5, the example sub-assembly 530 of FIGS. 5-6B, and the example assembly 700 of FIG. 7 disclosed herein may be included in any suitable electronic component. FIGS. 9-12 illustrate various examples of apparatus that may include or be included in the IC package 100 disclosed herein.

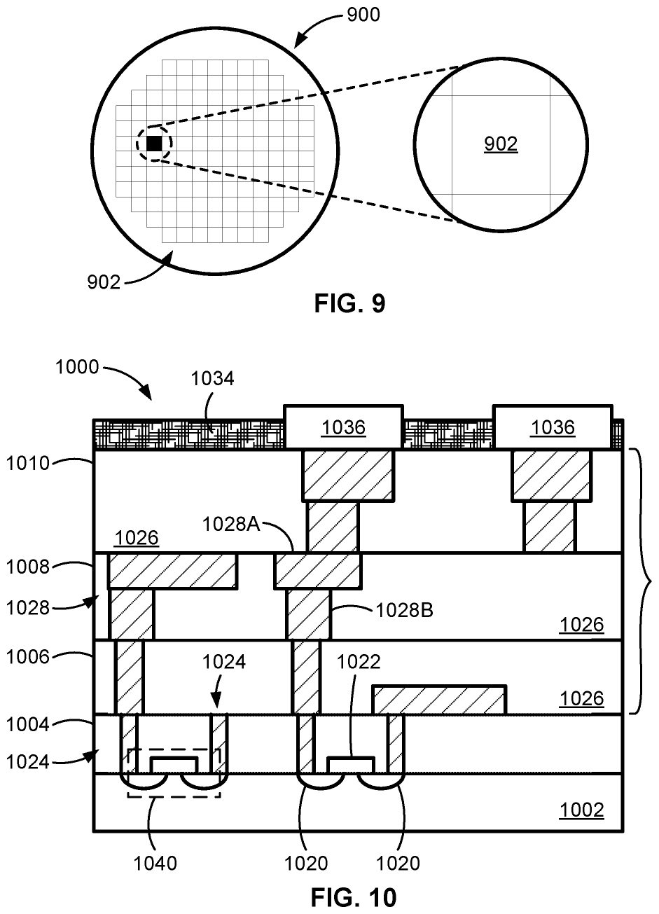

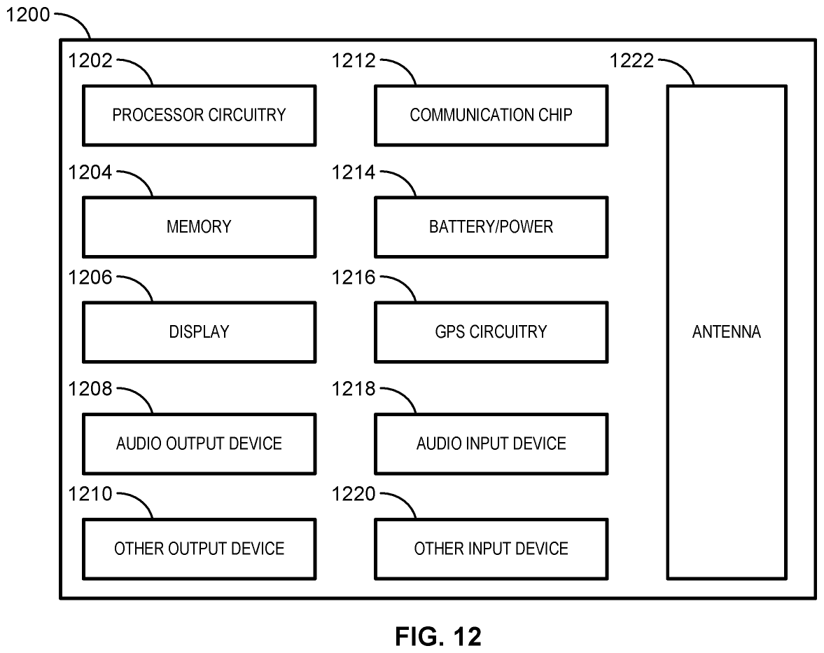

FIG. 9 is a top view of an example wafer 900 and dies 902 that may be included in the IC package 100 (e.g., as any suitable ones of the dies 106, 108). The wafer 900 may be composed of semiconductor material and may include one or more dies 902 having circuitry. Some or all of the dies 902 may be a repeating unit of a semiconductor product. After the fabrication of the semiconductor product is complete, the wafer 900 may undergo a singulation process in which the dies 902 are separated from one another to provide discrete “chips.” The die 902 may include one or more transistors (e.g., some of the transistors 1040 of FIG. 10, discussed below), supporting circuitry to route electrical signals to the transistors, passive components (e.g., traces, resistors, capacitors, inductors, and/or other circuitry), and/or any other components. In some examples, the die 902 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 902. For example, a memory array formed by multiple memory circuits may be formed on a same die 902 as programmable circuitry (e.g., the processor circuitry 1202 of FIG. 12) or other logic circuitry. Such memory may store information for use by the programmable circuitry. The example IC package 100 disclosed herein may be manufactured using a die-to-wafer assembly technique in which some dies 106, 108 are attached to a wafer 900 that include others of the dies 106, 108, and the wafer 900 is subsequently singulated.

FIG. 10 is a cross-sectional side view of an example IC device 1000 that may be included in the example IC package 100 (e.g., in any one of the dies 106, 108). One or more of the IC devices 1000 may be included in one or more dies 902 (FIG. 9). The IC device 1000 may be formed on an example die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more example device layers 1004 disposed on or above the die substrate 1002. The device layer 1004 may include features of one or more example transistors 1040 (e.g., metal oxide semiconductor field-effect transistors (MOSFETs)) formed on the die substrate 1002. The device layer 1004 may include, for example, one or more example source and/or drain (S/D) regions 1020, an example gate 1022 to control current flow between the S/D regions 1020, and one or more example S/D contacts 1024 to route electrical signals to/from the S/D regions 1020. The transistors 1040 may include additional features not depicted for the sake of clarity such as, for example, device isolation regions, gate contacts, and the like. The transistors 1040 are not limited to the type and configuration depicted in FIG. 10 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1040 may include an example gate 1022 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as for example a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1040 along the source-channel-drain direction, the gate electrode may include a U-shaped structure that includes a bottom portion substantially parallel to the surface of the die substrate 1002 and two sidewall portions that are substantially perpendicular to the top surface of the die substrate 1002. In other examples, at least one of the metal layers that form the gate electrode may be a planar layer that is substantially parallel to the top surface of the die substrate 1002 and does not include sidewall portions substantially perpendicular to the top surface of the die substrate 1002. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of respective ones of the transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes the dopants to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more example interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with example interconnect structures 1028 of the interconnect layers 1006-1010. The one or more interconnect layers 1006-1010 may form an example metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include example lines 1028a and/or example vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page from the perspective of FIG. 10. The vias 1028b may be arranged to route electrical signals in a direction of a plane that is substantially perpendicular to the surface of the die substrate 1002 upon which the device layer 1004 is formed. In some examples, the vias 1028b may electrically couple lines 1028a of different interconnect layers 1006-1010 together.

The interconnect layers 1006-1010 may include an example dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions. In other examples, the composition of the dielectric material 1026 between different interconnect layers 1006-1010 may be the same.

A first interconnect layer 1006 (referred to as Metal 1 or “M1”) may be formed directly on the device layer 1004. In some examples, the first interconnect layer 1006 may include lines 1028a and/or vias 1028b, as shown. The lines 1028a of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028b to couple the lines 1028a of the second interconnect layer 1008 with the lines 1028a of the first interconnect layer 1006. Although the lines 1028a and the vias 1028b are structurally delineated with a line within each interconnect layer (e.g., within the second interconnect layer 1008) for the sake of clarity, the lines 1028a and the vias 1028b may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 and/or the first interconnect layer 1006. In some examples, the interconnect layers that are “higher up” in the metallization stack 1019 in the IC device 1000 (i.e., further away from the device layer 1004) may be thicker.

The IC device 1000 may include an example solder resist material 1034 (e.g., polyimide or similar material) and one or more example conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

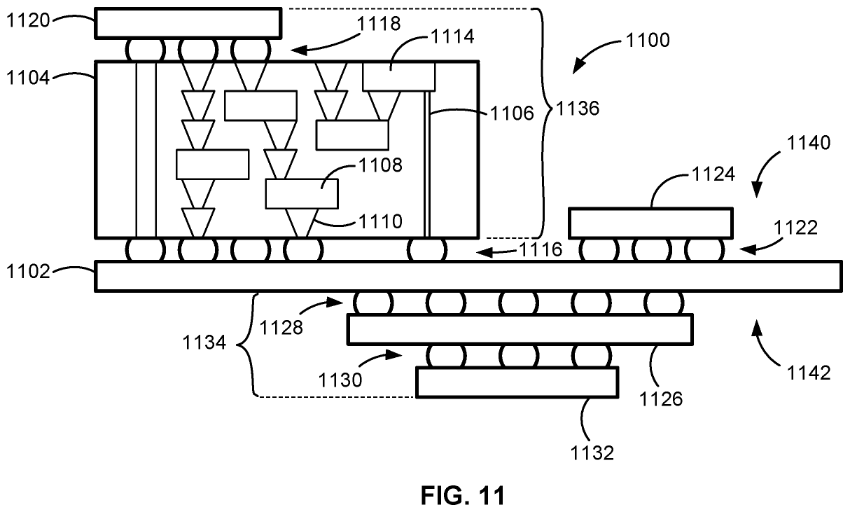

FIG. 11 is a cross-sectional side view of an example IC device assembly 1100 that may include the IC package 100 disclosed herein. In some examples, the IC device assembly corresponds to the IC package 100. The IC device assembly 1100 includes a number of components disposed on an example circuit board 1102 (which may be, for example, a motherboard). The IC device assembly 1100 includes components disposed on an example first face 1140 of the circuit board 1102 and an example opposing second face 1142 of the circuit board 1102. Any of the IC packages discussed herein with reference to the IC device assembly 1100 may take the form of the example IC package 100.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate. In some examples, the circuit board 1102 may be, for example, the circuit board 102 of FIG. 1.

The IC device assembly 1100 illustrated in FIG. 11 includes an example package-on-interposer structure 1136 coupled to the first face 1140 of the circuit board 1102 by example coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical, chemical, and/or mechanical coupling structure.

The package-on-interposer structure 1136 may include an example IC package 1120 coupled to an example interposer 1104 by example coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104. Additionally or alternatively, in some examples, additional interposers may be coupled to the interposer 1104. The interposer 1104 may provide an intervening substrate used to bridge the circuit board 1102 and the IC package 1120. The IC package 1120 may be or include, for example, a die (the die 902 of FIG. 9), an IC device (e.g., the IC device 1000 of FIG. 10), and/or any other suitable component(s). Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104. In other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include example metal interconnects 1108 and example vias 1110, including but not limited to example through-silicon vias (TSVs) 1106. The interposer 1104 may further include example embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an example IC package 1124 coupled to the first face 1140 of the circuit board 1102 by example coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes an example package-on-package structure 1134 coupled to the second face 1142 of the circuit board 1102 by coupling components 1128. The package-on-package structure 1134 may include a first example IC package 1126 and a second example IC package 1132 coupled together by example coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above.

FIG. 12 is a block diagram of an example electrical device 1200 that may include one or more of the example IC package 100 and/or the example PCB 102 containing anyone of the example conductive layer 300 of FIGS. 3 and 4, the example assembly 500 of FIG. 5, the example sub-assembly 530 of FIGS. 5-6B, and the example assembly 700 of FIG. 7. For example, any suitable ones of the components of the electrical device 1200 may include one or more of the device assemblies 1100, IC devices 1000, or dies 902 disclosed herein, and may be arranged in the example IC package 100. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in some examples, the electrical device 1200 may not include one or more of the components illustrated in FIG. 12, but the electrical device 1200 may include interface circuitry for coupling to the one or more components. For example, the electrical device 1200 may not include an example display 1206, but may include display interface circuitry (e.g., a connector and driver circuitry) to which the display 1206 may be coupled. In some examples, the electrical device 1200 may not include an example audio input device 1218 (e.g., microphone) or an example audio output device 1208 (e.g., a speaker, a headset, earbuds, etc.), but may include audio input or output device interface circuitry (e.g., connectors and supporting circuitry) to which the audio input device 1218 or the audio output device 1208 may be coupled.

The electrical device 1200 may include example programmable or processor circuitry 1202 (e.g., one or more processing devices). The processor circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1200 may include an example memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the processor circuitry 1202. This memory may be used as cache memory and may include embedded dynamic random access memory (eDRAM) or spin transfer torque magnetic random access memory (STT-MRAM).

In some examples, the electrical device 1200 may include an example communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an example antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include example battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include the display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include the audio output device 1208 (or corresponding interface circuitry, as discussed above). The audio output device 1208 may include any device that generates an audible indicator, such as speakers, headsets, or earbuds.

The electrical device 1200 may include the audio input device 1218 (or corresponding interface circuitry, as discussed above). The audio input device 1218 may include any device that generates a signal representative of a sound, such as microphones, microphone arrays, or digital instruments (e.g., instruments having a musical instrument digital interface (MIDI) output).

The electrical device 1200 may include example GPS circuitry 1216. The GPS circuitry 1216 may be in communication with a satellite-based system and may receive a location of the electrical device 1200, as known in the art.

The electrical device 1200 may include any other example output device 1210 (or corresponding interface circuitry, as discussed above). Examples of the other output device 1210 may include an audio codec, a video codec, a printer, a wired or wireless transmitter for providing information to other devices, and/or an additional storage device.

The electrical device 1200 may include any other example input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1200 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1200 may be any other electronic device that processes data.

From the foregoing, it will be appreciated that example systems, apparatus, articles of manufacture, and methods have been disclosed that reduce crosstalk and impedance discontinuities in IC packages. Examples disclosed herein provide bridges that traverse example voids in conductive layers within a package substrate and/or within a printed circuit board. Examples disclosed herein position metal traces adjacent to (e.g., aligned with) the bridges to reduce capacitive coupling between adjacent conductive layers (e.g., the traces and contact pads on opposite sides of the bridges), thereby reducing cross-talk and enabling better performance and/or denser routing with fewer conductive layers. Thus, disclosed examples improve the electrical performance of example IC packages by implementing bridges across example void regions in an example conductive layer.

Example 1 includes a substrate for an electronic circuit comprising a first conductive layer having an aperture extending through the first conductive layer, the aperture aligned with a contact pad, the first conductive layer including an arm extending from a first location on a perimeter of the aperture to a second location on the perimeter of the aperture, and a second conductive layer adjacent to the first conductive layer, the second conductive layer including a metal trace positioned adjacent to the arm, the arm between the metal trace and the contact pad.

Example 2 includes the substrate of example 1, further including a dielectric material to fill the aperture, the dielectric material between the arm and the contact pad.

Example 3 includes the substrate of example 1, wherein the contact pad is electrically and mechanically coupled to a conductive ball, the contact pad positioned between the arm and the conductive ball, the conductive ball to facilitate connection with a printed circuit board (PCB).

Example 4 includes the substrate of example 1, wherein the aperture has a rectangular shape.

Example 5 includes the substrate of example 1, wherein the aperture has a circular shape.

Example 6 includes the substrate of example 1, wherein the aperture has a hexagonal shape.

Example 7 includes the substrate of example 1, wherein the aperture is a first aperture, further including a third conductive layer between the first and second conductive layers, the third conductive layer having a second aperture aligned with the first aperture.

Example 8 includes the substrate of example 1, wherein the aperture is a first aperture and the contact pad is a first contact pad, further including a second aperture extending through the first conductive layer, the second aperture spaced apart from the first aperture, the second aperture aligned with a second contact pad, a portion of the metal trace extending away from the second location of the first aperture towards a third location on a perimeter of the second aperture, the metal trace electrically coupled to the second contact pad.

Example 9 includes the substrate of example 1, wherein the arm extends in a first direction across the aperture, and a portion of the metal trace extends along the first direction.

Example 10 includes the substrate of example 9, wherein the portion is a first portion, a second portion of the metal trace extending along a second direction different from the first direction, the second portion positioned between the first location and the second location.

Example 11 includes the substrate of example 1, wherein the arm includes a first linear segment and a second linear segment, the first linear segment angled relative to the second linear segment, the first and second linear segments connected at a point between the first and second locations of the aperture.

Example 12 includes an integrated circuit (IC) package comprising a semiconductor die, and a package substrate including a contact pad on a first side of the package substrate, the semiconductor die attached to a second side of the package substrate opposite the first side, and a conductive layer having a first cavity and a second cavity, a bridge separating the first cavity from the second cavity, the first cavity between the contact pad and the semiconductor die in a first direction normal to a plane of the conductive layer, the second cavity between the contact pad and the semiconductor die in the first direction, the bridge between the contact pad and the semiconductor die in the first direction.

Example 13 includes the IC package of example 12, wherein the bridge includes a bend within the plane of the conductive layer.

Example 14 includes the IC package of example 12, wherein the bridge includes a first segment and a second segment, the first segment extending from a side of the second segment to at least one edge of the first cavity.

Example 15 includes the IC package of example 12, wherein the bridge defines an edge of the first cavity.

Example 16 includes the IC package of example 12, wherein the conductive layer is a first conductive layer, the IC package further including a second conductive layer positioned between the first conductive layer and the semiconductor die, the second conductive layer including a metal trace positioned between the bridge and the semiconductor die in the first direction.

Example 17 includes the IC package of example 16, wherein the bridge has a first shape, the metal trace having a second shape aligned with the first shape.

Example 18 includes a method comprising providing a first conductive layer, the first conductive layer including a metal trace, and providing a second conductive layer, the second conductive layer including an opening and a bridge connecting a first side of the opening to a second side of the opening, the bridge between the metal trace and a contact pad.

Example 19 includes the method of example 18, further including adding a dielectric material to fill the opening, the dielectric material between the bridge and the contact pad.

Example 20 includes the method of example 18, further including coupling the metal trace to the contact pad by a metal interconnect extending through the opening.

The following claims are hereby incorporated into this Detailed Description by this reference Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate for an electronic circuit comprising:
a first conductive layer having an aperture extending through the first conductive layer, the aperture aligned with a contact pad, the first conductive layer including an arm extending from a first location on a perimeter of the aperture to a second location on the perimeter of the aperture; and
a second conductive layer adjacent to the first conductive layer, the second conductive layer including a metal trace positioned adjacent to the arm, the arm between the metal trace and the contact pad.

2. The substrate of claim 1, further including a dielectric material to fill the aperture, the dielectric material between the arm and the contact pad.

3. The substrate of claim 1, wherein the contact pad is electrically and mechanically coupled to a conductive ball, the contact pad positioned between the arm and the conductive ball, the conductive ball to facilitate connection with a printed circuit board (PCB).

4. The substrate of claim 1, wherein the aperture has a rectangular shape.

5. The substrate of claim 1, wherein the aperture has a circular shape.

6. The substrate of claim 1, wherein the aperture has a hexagonal shape.

7. The substrate of claim 1, wherein the aperture is a first aperture, further including a third conductive layer between the first and second conductive layers, the third conductive layer having a second aperture aligned with the first aperture.

8. The substrate of claim 1, wherein the aperture is a first aperture and the contact pad is a first contact pad, further including a second aperture extending through the first conductive layer, the second aperture spaced apart from the first aperture, the second aperture aligned with a second contact pad, a portion of the metal trace extending away from the second location of the first aperture towards a third location on a perimeter of the second aperture, the metal trace electrically coupled to the second contact pad.

9. The substrate of claim 1, wherein the arm extends in a first direction across the aperture, and a portion of the metal trace extends along the first direction.

10. The substrate of claim 9, wherein the portion is a first portion, a second portion of the metal trace extending along a second direction different from the first direction, the second portion positioned between the first location and the second location.

11. The substrate of claim 1, wherein the arm includes a first linear segment and a second linear segment, the first linear segment angled relative to the second linear segment, the first and second linear segments connected at a point between the first and second locations of the aperture.

12. An integrated circuit (IC) package comprising:
a semiconductor die; and
a package substrate including:
a contact pad on a first side of the package substrate, the semiconductor die attached to a second side of the package substrate opposite the first side; and
a conductive layer having a first cavity and a second cavity, a bridge separating the first cavity from the second cavity, the first cavity between the contact pad and the semiconductor die in a first direction normal to a plane of the conductive layer, the second cavity between the contact pad and the semiconductor die in the first direction, the bridge between the contact pad and the semiconductor die in the first direction.

13. The IC package of claim 12, wherein the bridge includes a bend within the plane of the conductive layer.

14. The IC package of claim 12, wherein the bridge includes a first segment and a second segment, the first segment extending from a side of the second segment to at least one edge of the first cavity.

15. The IC package of claim 12, wherein the bridge defines an edge of the first cavity.

16. The IC package of claim 12, wherein the conductive layer is a first conductive layer, the IC package further including a second conductive layer positioned between the first conductive layer and the semiconductor die, the second conductive layer including a metal trace positioned between the bridge and the semiconductor die in the first direction.

17. The IC package of claim 16, wherein the bridge has a first shape, the metal trace having a second shape aligned with the first shape.

18. A method comprising:
providing a first conductive layer, the first conductive layer including a metal trace; and
providing a second conductive layer, the second conductive layer including an opening and a bridge connecting a first side of the opening to a second side of the opening, the bridge between the metal trace and a contact pad.

19. The method of claim 18, further including adding a dielectric material to fill the opening, the dielectric material between the bridge and the contact pad.

20. The method of claim 18, further including coupling the metal trace to the contact pad by a metal interconnect extending through the opening.
